(19) United States
(12) Patent Application Publication
(10) Pub. No.: US 2004/0163592 A1
(43) Pub. Date: Aug. 26, 2004

(54) Mask for vacuum deposition and organic EL display panel manufactured by using the same

(75) Inventors: Hirosi Abiko, Yonezawa-shi (JP); Akira Takahashi, Yonezawa-shi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: TOHOKU POINEER CORPORATION, Tendo-shi (JP)

(21) Appl. No.: 10/778,550

(22) Filed: Feb. 17, 2004

(30) Foreign Application Priority Data
Feb. 20, 2003 (JP) 2003-043229

(51) Int. Cl. C23C 16/00

(52) U.S. Cl. 118/715

(57) ABSTRACT

A mask for vacuum deposition capable of adjusting tension of a mask for vacuum deposition and easily dismounting the mask for vacuum deposition from a mask frame and an organic EL display panel are provided. A mask 1 for vacuum deposition that is held by a mask frame 11 is provided. The mask comprises a mask body 10 for vacuum deposition; a guide member 12 adhered to at least one side of the mask body 10 for vacuum deposition; a tension applying means 14 for applying predetermined tension to the mask body 10 for vacuum deposition via the guide member 12 when the guide member 12 is held by the mask frame 11; and a fixing means 21 for fixing the guide member and mask frame in the vertical direction to a mask surface.

### BACKGROUND OF THE INVENTION

1. Field of the Invention

The present invention relates to a mask for vacuum deposition and an organic EL (electroluminescence) display panel manufactured by using the same.

2. Description of the Related Art

In recent years, as colorization goes forward, a minimum pitch between pixels (for R, G, and B pixels) of a light emitting device such as an organic EL has been made as fine as nearly 50 μm, and additionally a study of a still smaller pixel has been also conducted.

On the other hand, the size of a mask for vacuum deposition used for manufacturing the organic EL is as large as about from 400 mm to 500 mm and there has been a tendency for the mask for vacuum deposition to become larger with the increasing size of a display panel such as the organic EL.

In this manner, the mask for vacuum deposition has been made larger in size and a mask pitch has been made smaller. If the mask pitch of the mask for vacuum deposition that is made larger in size is made smaller, then the rigidity of the mask for vacuum deposition itself is decreased and thus when the mask for vacuum deposition is fixed to a mask frame of its holding member, a deflection is produced, so that it is necessary to apply tension to the mask for vacuum deposition.

For this reason, in the related art, in a state where tension is applied to the mask for vacuum deposition to remove the deflection, an end portion of the mask for vacuum deposition is bonded to the mask frame with an adhesive or is fixed thereto by welding, or the end portion of the mask for vacuum deposition is clamped with screws.

Further, an example of means for applying tension is a method called “press fitting method” used for framing a metal mask for screen printing. This includes a method of holding and fixing the metal mask between a recess of a printing plate frame and a presser to be fitted in the recess. (see Kokai, Unexamined Patent Publication No. H9-142053).

However, the conventional method of fixing the mask for vacuum deposition to the mask frame presents a problem that since it is difficult to adjust the tension of the mask for vacuum deposition after it is fixed, it is impossible to correct the mask for vacuum deposition when it is deflected by some causes after it is fixed.

Moreover, the conventional method of fixing the mask for vacuum deposition to the mask frame presents problems that it is difficult to dismount to clean the mask for vacuum deposition from the mask frame, that it is impossible to change the mask for vacuum deposition and reuse the mask frame when a mask pattern of the mask for vacuum deposition is changed.

Moreover, since the above-mentioned “press fitting method” used for the frame tension of the metal mask for screen printing does not allow the tension to be adjusted finely, it is difficult to apply this method to the mask for vacuum deposition of the organic EL display panel which needs better accuracy.

### SUMMARY OF THE INVENTION

The present invention has been made to solve the above-mentioned problems. It is an object of the present invention to provide a mask for vacuum deposition that is not directly welded to a mask frame so that the tension of the mask for vacuum deposition can be adjusted in a state where it is held by the mask frame and that can be easily removed from the mask frame, and an organic EL display panel manufactured by using the same.

A mask for vacuum deposition in accordance with the present invention is a mask for vacuum deposition that is held by a mask frame and is characterized by comprising a mask body for vacuum deposition, a guide member fixed to at least one side of the mask body for vacuum deposition, a tension applying means for applying predetermined tension to the mask body for vacuum deposition via the guide member when the guide member is held by the mask frame, and a fixing means for fixing the guide member and the mask frame in the vertical direction to the mask surface.

As described above, since the mask for vacuum deposition is not directly bonded to the mask frame, the mask for vacuum deposition can be easily dismounted from the mask frame. Further, since the predetermined tension is applied to at least one side of the mask frame, when the mask for vacuum deposition is held by the mask frame, a deflection of the mask body for vacuum deposition can be prevented.

Especially, since the fixing means for fixing the guide member and the mask frame in the vertical direction to the mask surface is provided, when tension is applied to the horizontal direction of the mask body for vacuum deposition, it is possible to prevent the guide member from being lifted in the vertical direction, so that a shift and the deflection of the mask body for vacuum deposition due to the lifting may be avoided.

Moreover, as for the mask for vacuum deposition in accordance with the present invention, it is preferable that the mask body for vacuum deposition has the mask pattern in which apertures are arranged in a predetermined pattern and has the guide member fixed to at least one side in the direction perpendicular to the longitudinal direction of the aperture.

This makes it possible to apply tension in the direction along the arrangement of the predetermined pattern and to stretch the mask body for vacuum deposition so as to prevent the deflection of the mask body for vacuum deposition. Therefore, deposited pixels can be formed in more accurate shapes.

Further, as for the mask for vacuum deposition in accordance with the present invention, it is preferable that the guide members are fixed to two sides of the mask body for vacuum deposition that are opposed to each other.

This makes it possible to apply tension in two directions, the forward/rearward direction and left/right direction and thus to prevent the deflection of the mask for vacuum deposition more surely.

As for the mask for vacuum deposition in accordance with the present invention, it is preferable that the guide members are fixed to four sides of the mask body for vacuum deposition.

This makes it possible to apply tension in four directions, that is, in all directions of forward and rearward directions and right and left directions and thus to more surely prevent the deflection of the mask for vacuum deposition. Moreover, one of facing sides may directly be bonded to a tray.

Further, as for the mask for vacuum deposition in accordance with the present invention, it is preferable that the tension applying means includes a threaded hole formed at a side wall of the guide member and a screw which is screwed into the threaded hole and whose tip portion is abutted against a side surface of the mask frame.

Furthermore, it is characterized in that a hole is formed at the side surface of the mask frame and the screw passing through the hole and a tip portion of the screw is abutted against a bottom surface portion of the hole.

Such a tension applying means makes it possible to prevent the deflection of the mask for vacuum deposition more surely and easily.

Moreover, as for the mask for vacuum deposition in accordance with the present invention, it is preferable that the tension applying means includes a through hole formed at the side wall of the guide member, the screw which is passed through the through hole and whose tip portion is screwed into the threaded hole formed at a side wall of the mask frame, and a spring member provided between the mask frame and the guide member.

Further, it is preferable that the spring member is a compression spring or a leaf spring. This makes it possible to prevent the deflection of the mask for vacuum deposition more surely.

Moreover, the fixing means for fixing the guide member and the mask frame in the vertical direction to the mask surface may be a clip member for clipping the mask frame and the guide member in the longitudinal direction of the guide member. Further, the fixing means for fixing the guide member and mask frame in the vertical direction to the mask surface may be a clip member for clipping the mask frame and the guide member at four corners of the mask body for vacuum deposition.

Moreover, the fixing means for fixing the guide member and the mask frame in the vertical direction to the mask surface may comprise a through hole formed at a wall surface of the guide member, a through hole formed at the side surface of the mask frame, and a pin to be passed through the through hole of the guide member and the through hole of the mask frame.

Such a fixing means makes it possible to prevent more surely and easily the guide member from being lifted in the vertical direction when the tension is applied in the horizontal direction of the mask body for vacuum deposition, so that the shift and the deflection of the mask body for vacuum deposition due to the lifting may be avoided.

An organic EL display panel in accordance with the present invention is characterized by being manufactured by using a mask for vacuum deposition which is a mask for vacuum deposition held by a mask frame and comprises a mask body for vacuum deposition, a guide member fixed to at least one side of the mask body for vacuum deposition, a tension applying means for applying predetermined tension to the mask body for vacuum deposition via the guide member when the guide member is held by the mask frame, and a fixing means for fixing the guide member and the mask frame in the vertical direction to the mask surface.

The use of such a mask for vacuum deposition makes it possible to form deposited pixels in more accurate shapes in the organic EL display panel made of a light emitting device having a finer pixel pitch and thus to produce an organic EL display panel capable of displaying an image of high quality.

Moreover, it is preferable that the mask body for vacuum deposition has the mask pattern in which apertures are arranged in the predetermined pattern, and is fixed the guide member to at least one side of the mask body in the direction perpendicular to the longitudinal direction of the aperture.

Further, it is preferable that the tension applying means includes the threaded hole formed at the side wall of the guide member and the screw which is screwed into the threaded hole and whose tip portion is abutted against the side surface of the mask frame.

Moreover, it is preferable that the tension applying means includes the through hole formed at the side wall of the guide member, the screw which is passed through the through hole and whose tip portion is screwed into the through hole made at the side surface of the mask frame, and the spring member provided between the mask frame and the guide member.

Moreover, the fixing means for fixing the guide member and the mask frame in the vertical direction to the mask surface may be the clip member for clipping the mask frame and the guide member in the longitudinal direction of the guide member, and also may be the clip member for clipping the mask frame and the guide member at the four corners of the mask body for vacuum deposition.

Moreover, it is preferable that the fixing means for fixing the guide member and the mask frame in the vertical direction to the mask surface comprises the through hole formed at the wall surface of the guide member, the through hole formed at the side surface of the mask frame, and the pin to be passed through the through hole of the guide member and the through hole of the mask frame.

Such a fixing means makes it possible to easily and surely prevent the guide member from being lifted in the vertical direction when the tension is applied to the horizontal direction of the mask body for vacuum deposition, so that the shift and the deflection of the mask body for vacuum deposition due to the lifting may be avoided, whereby it is possible to form deposited pixels in more accurate shapes and manufacture an organic EL display panel capable of displaying an image of high quality.

### BRIEF DESCRIPTION OF THE DRAWINGS

FIG. 1 is a perspective view showing a mask for vacuum deposition in a preferred embodiment in accordance with the present invention and is illustrative of a state where the mask for vacuum deposition is dismounted from a mask frame;

FIG. 2 is a perspective view showing the mask for vacuum deposition in the preferred embodiment in accordance with the present invention and is illustrative a state where the mask for vacuum deposition is mounted on the mask frame;

FIG. 3 is a perspective view showing a main part of the preferred embodiment in accordance with the present invention;

FIGS. 4(a), 4(b), and 4(c) are cross-sectional views respectively illustrating examples (a), (b), (c) of a tension applying means as taken along a line A-A in FIG. 3;

FIG. 5 is a perspective view of a compression coil spring;

FIG. 6 is a perspective view of the mask for vacuum deposition for showing an example 1 of a fixing means;

FIG. 7 is a perspective view of the mask for vacuum deposition for showing an example 2 of the fixing means;

FIG. 8(a) is a perspective view of an edge part of the mask for vacuum deposition for showing an example 3 of the fixing means; and

FIG. 8(b) is a cross-sectional view taken along a line B-B of FIG. 8(a).

### DESCRIPTION OF THE PREFERRED EMBODIMENTS

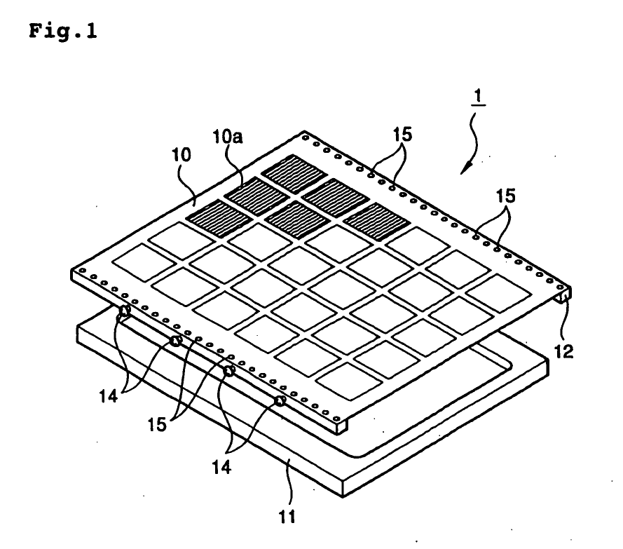

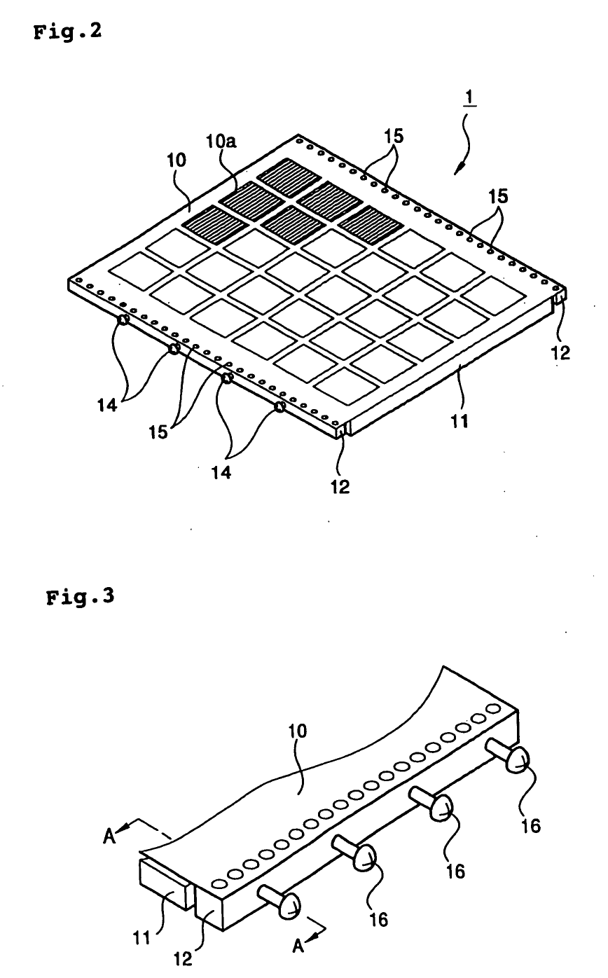

In the preferred embodiments in accordance with the present invention, a case will be described in detail where a mask for vacuum deposition in accordance with the present invention is applied to the vacuum deposition of an organic layer when an organic EL display panel is manufactured. FIG. 1 and FIG. 2 illustrate the mask for vacuum deposition in a preferred embodiment in accordance with the present invention.

A mask 1 for vacuum deposition in the preferred embodiment in accordance with the present invention forms an organic EL device and is held by a mask frame 11 in a deposition process (mainly in forming an organic layer) when the organic EL device is manufactured.

As shown in FIG. 1, the mask 1 for vacuum deposition has a mask body 10 for vacuum deposition, guide members 12, and a tension applying means 14.

The mask body 10 for vacuum deposition and the mask frame 11 are of stainless steel, such as SUS344, SUS303, SUS316, SUS430, Ti (titanium), other metals or ceramics. Further, the mask frame 11 has a thickness of from about 1 mm to about 100 mm, preferably, from about 4 mm to about 30 mm.

More specifically, as shown in FIG. 1, as for the mask 1 for vacuum deposition, two oppositely facing sides of the mask body 10 for vacuum deposition are fixed to the guide members 12, 12 by spot welding and the like. The connection may be achieved by means of an adhesive or a clamp, so that the mask and the guide may only be fixed.

Then, these guide members 12, 12 have substantially the same length as the mask body 10 for vacuum deposition.

Moreover, these guide members 12, 12 are equipped with the tension applying means 14, 14 for applying the predetermined tension to the mask body 10 for vacuum deposition.

Then, mask patterns 10a are formed on the mask body 10 for vacuum deposition. Since the mask patterns 10a are used for depositing pixels etc. for constituting the organic EL display, the grid-like mask patterns 10a having fine pitches are formed.

Each of the mask patterns 10a is formed in such a way that the apertures are arranged in the predetermined pattern. The apertures are formed in the shape of a slit, a slot, a circle or the like and arranged in a square, in a stagger or the like.

If tension is applied to the mask body 10 for vacuum deposition in the direction along the arrangement of the apertures of the mask patterns 10a as described above to stretch the mask body 10 for vacuum deposition so as to remove its deflection, it is possible to form the pixels to be deposited in more accurate shape. Therefore, as shown in FIG. 1 and FIG. 2, the guide members 12, 12 are fixed to the two oppositely facing sides of the mask body 10 for vacuum deposition which are arranged in the direction perpendicular to the longitudinal direction of the mask pattern 10a.

Then, as shown in FIG. 2, by mounting the mask 1 for vacuum deposition on the mask frame 11, a deposition operation can be performed.

Further, a structure for applying tension to the mask body when the mask 1 for vacuum deposition is mounted on the mask frame 11 will be described in detail.

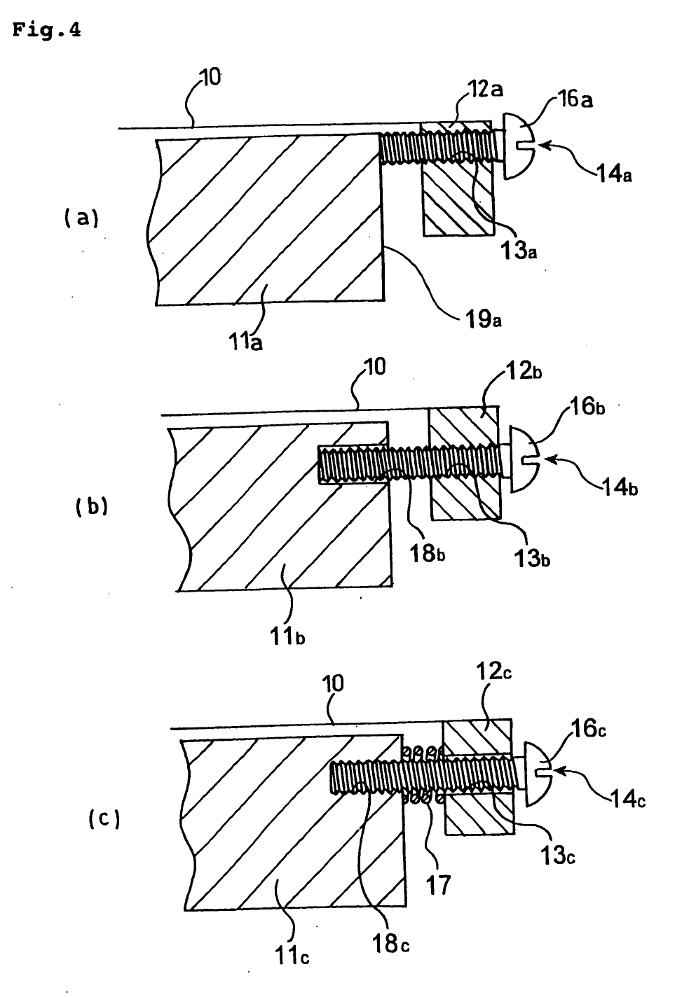

FIG. 3 is the perspective view showing the main part of the preferred embodiment in accordance with the present invention for describing a structure for applying tension to the mask body. FIGS. 4(a), 4(b), and 4(c) are the cross-sectional views as taken along the line A-A in FIG. 3.

FIG. 3 illustrates one side to which the guide member 12 as in FIG. 1 is fixed, in which screws 16, which are the parts of the tension applying means 14, are fixed to the side surface of the guide member 12.

Further, as an example of structure of the tension applying means 14, examples as shown in the cross-sectional views of the FIGS. 4(a), 4(b), and 4(c) are illustrated.

Firstly, in an example of structure of FIG. 4(a), a tension applying means 14a includes a threaded hole 13a formed at a side wall of a guide member 12a and a screw 16a which is screwed into the threaded hole 13a and whose tip portion is abutted against a side surface 19a of a mask frame 11a.

Further, in an example of structure of FIG. 4(b), a tension applying means 14b includes a threaded hole 13b formed at a side wall of a guide member 12b and a screw 16b which is screwed into a threaded hole 13b and passed through a hole 18b formed at a side surface of a mask frame 11b. A tip portion of the screw 16b is abutted against a bottom surface portion of the hole 18b.

By screwing the screws 16a, 16b, tension can be generated in the mask body 10. Moreover, the hole 18b is useful for preventing the guide member 12b from rattling and the tip portion of the screw from shifting when the screw 16b is turned.

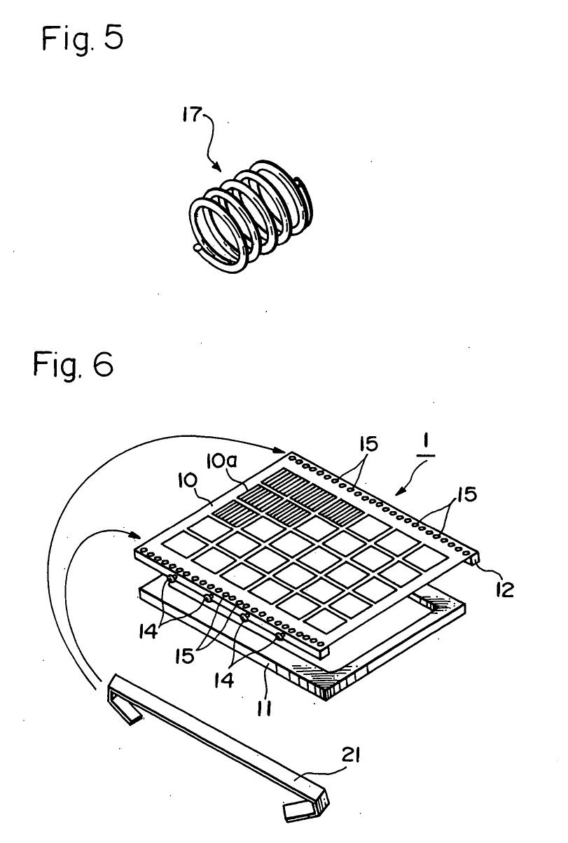

Further, in an example of structure of FIG. 4(c), a tension applying means 14c includes a through hole 13c formed at a side wall of the guide member 12c, a screw 16c which is passed through the through hole 13c and whose tip portion is screwed into a threaded hole 18c formed at a side surface of the mask frame 11c, and a compression coil spring 17 (see FIG. 5) which is a spring member provided between a mask frame 11c and a guide member 12c.

In the example of structure of FIG. 4(c), the compression coil spring 17 in a state of the compression can be stretched by the screw 16c, so that the tension in the mask body 10 may be generated by unscrewing the screw 16c. In addition, the spring member may be a spring having a similar function, such as a leaf spring, instead of the compression coil spring 17.

The tension applying means 14 (14a, 14b, 14c) are constructed as shown in the examples of FIGS. 4(a), 4(b), and 4(c), so that the guide members 12 (12a, 12b, 12c) respectively engaging with the screws 16 (16a, 16b, 16c) can be moved by turning the screws 16 (16a, 16b, 16c), to thereby adjust tension applied to the mask body 10. In other words, by adjusting a protrusion distance of each of the screws 16 from the side wall of the guide member 12, the tension applied to the mask body 10 can be adjusted.

A method of adjusting the tension of the mask body 10 includes a method of bringing the mask body 10 into a state where the mask body 10 is not wrinkled visually, a method of measuring torque of the respective screws and rendering the torque in a fixed value, and a method of adjusting the respective screws so that an error between an alignment mark on the mask and an alignment mark on a scale is smaller than a predetermined value.

A standard screw such as M2 to M5 may be used as the screws 16 (16a, 16b, 16c) described above. Here, the pitch of M2 is 0.4 mm, the pitch of M3 is 0.5 mm, the pitch of M4 is 0.7 mm, and the pitch of M5 is 0.8 mm.

As described above, as for the mask 1 for vacuum deposition in accordance with the present embodiment, the guide members 12, 12 are removed from the mask frame 11, so that the mask body 10 for vacuum deposition can be easily dismounted from the mask frame 11.

Therefore, the mask body 10 for vacuum deposition and the mask frame 11 can be easily cleaned, and when the mask pattern 10a is changed, the mask body 10 for vacuum deposition can be easily changed by reusing the mask frame 11.

In addition, a fixing means for fixing the guide member 12 and the mask frame 11 in the vertical direction to the surface of the mask body 10 for vacuum deposition may be provided. Hereinafter, it is described with reference to examples 1 to 3 of the fixing means.

### EXAMPLE 1

As shown in FIG. 6, at both ends of the mask body 10 for vacuum deposition, a clip 21 in a shape of a long strip, as the fixing means, is fixed in the vertical direction along the longitudinal direction of the guide member 12 (as indicated by arrows in FIG. 6), so as to clip and hold the mask frame 11 and the guide member 12.

### EXAMPLE 2

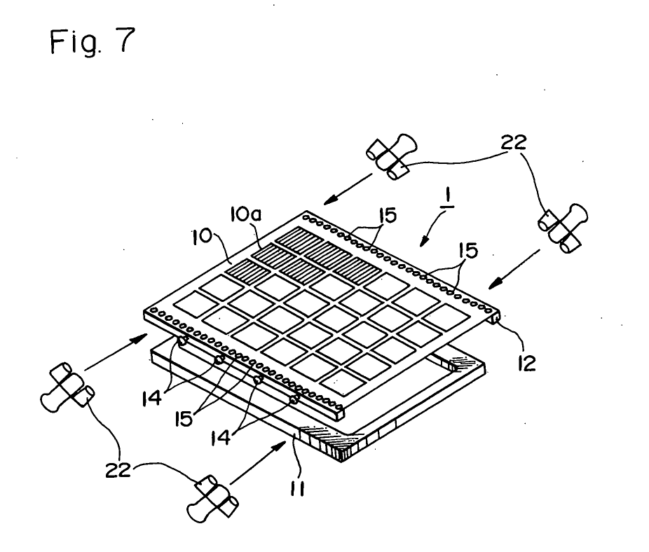

Alternatively, by using clips 22 as shown in FIG. 7, the mask frame 11 and the guide member 12 are fixed so as to be clipped and held at the four corners of the mask body 10 for vacuum deposition in the vertical direction as indicated by arrows.

### EXAMPLE 3

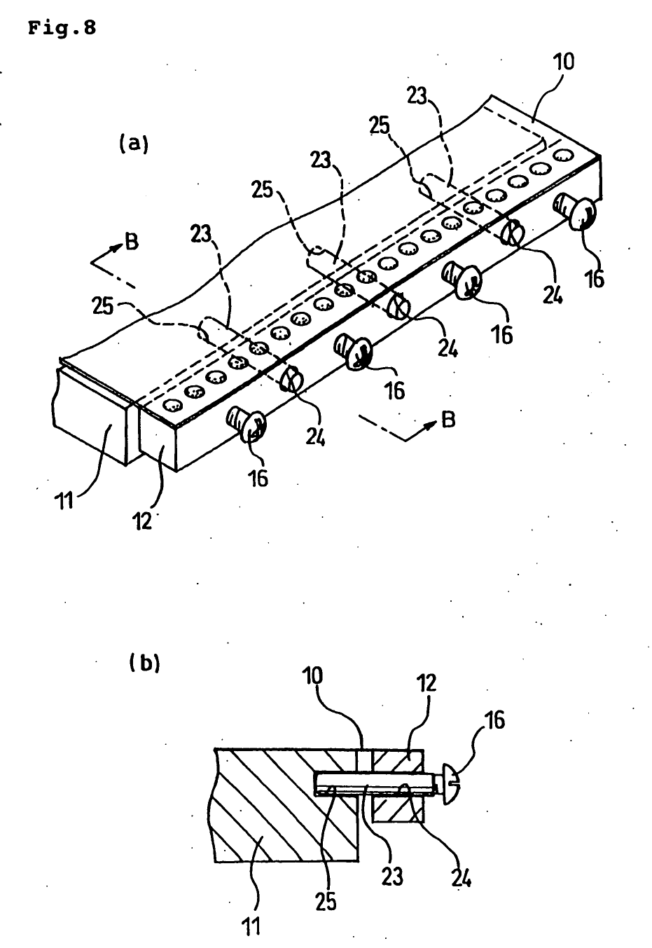

FIG. 8(a) is a perspective view of an edge portion of the mask for vacuum deposition showing an example 3 of the fixing means, and FIG. 8(b) is a cross-sectional view taken along the line B-B of FIG. 8(a).

The fixing means of the example 3, as shown in FIG. 8(a) and FIG. 8(b), comprises a through hole 24 formed at the side wall of the guide member 12 and a hole 25 formed at the side surface of the mask frame 11 between screws 16, 16 fixed to the side surface of the guide member 12, and fixes the mask frame 11 in the vertical direction by passing a pin 23 through the through hole 24 and inserting the pin 23 into the hole 25.

Instead of the fixing means as described above, the guide member 12 may be fixed in the vertical direction to the mask frame 11 by passing a screw through a through hole formed in the vertical direction to the mask surface of the mask frame 11, and screwing a tip portion of the screw into a threaded hole formed in the vertical direction to the mask surface of the guide member 12.

It should be noted that, in the above-mentioned embodiment, the guide members 12, 12 are fixed to the two oppositely facing sides of the mask body 10 for vacuum deposition in order to apply the tension to the mask body 10 for vacuum deposition, however, it is also possible to apply the tension to the four sides of the mask body 10 for vacuum deposition by fixing the guide members 12 to the respective four sides of the mask body 10 for vacuum deposition. In this case, it is possible to more surely prevent the deflection of the mask body 10 for vacuum deposition.

As described above in detail, according to the mask for vacuum deposition in accordance with the present invention, the mask for vacuum deposition which is held by the mask frame comprises the mask body for vacuum deposition, the guide member fixed to at least one side of the mask body for vacuum deposition, the tension applying means for applying the predetermined tension to the mask body for vacuum deposition via the guide member when the guide member is held by the mask frame, and the fixing means for fixing the guide member and the mask frame in the vertical direction to the mask surface, so that the mask for vacuum deposition can be easily dismounted from the mask frame. Moreover, the predetermined tension is applied to at least one of the sides, so that the deflection of the mask body for vacuum deposition can be prevented when the mask for vacuum deposition is held at the mask frame.

Especially, since the fixing means for fixing the guide member and the mask frame in the vertical direction to a mask surface are comprised, when tension is applied to the horizontal direction of the mask body for vacuum deposition, it is possible to prevent the guide member from being lifted in the vertical direction, and the shift and the deflection of the mask body for vacuum deposition due to the lifting may be avoided.

The organic EL display panel in accordance with the present invention is manufactured by using the mask for vacuum deposition which is held by a mask frame and comprises the mask body for vacuum deposition, the guide member fixed to at least one side of the mask body for vacuum deposition, the tension applying means for applying the predetermined tension to the mask body for vacuum deposition via the guide member when the guide member is held by the mask frame, and the fixing means for fixing the guide member and the mask frame in the vertical direction to the mask surface, so that it is possible to form deposited pixels in more accurate shapes for the organic EL display panel having a finer pixel pitch of electroluminescence elements and to manufacture the organic EL display panel capable of displaying the image of high quality.

What is claimed is:

1. A mask for vacuum deposition that is held by a mask frame, the mask comprising:
a mask body for vacuum deposition;
a guide member fixed to at least one side of said mask body for vacuum deposition;
a tension applying means for applying predetermined tension to said mask body for vacuum deposition via said guide member when said guide member is held by said mask frame; and
a fixing means for fixing said guide member and said mask frame in a vertical direction to a mask surface.

2. The mask for vacuum deposition as claimed in claim 1, wherein said mask body for vacuum deposition has a mask pattern in which apertures are arranged in a predetermined pattern and has said guide member fixed to at least one side in the direction perpendicular to the longitudinal direction of said aperture.

3. The mask for vacuum deposition as claimed in claim 2, wherein said guide members are fixed to two oppositely facing sides of said mask body for vacuum deposition.

4. The mask for vacuum deposition as claimed in any one of claims 1 to 3, wherein said guide members are fixed to four sides of said mask body for vacuum deposition.

5. The mask for vacuum deposition as claimed in claim 1, wherein said tension applying means includes a threaded hole formed at a side wall of said guide member and a screw which is screwed into said threaded hole and whose tip portion is abutted against a side surface portion of said mask frame.

6. A mask for vacuum deposition as claimed in claim 5, wherein a hole is formed at a side surface of said mask frame, said hole allows said screw to pass through, and the tip portion of said screw is abutted against a bottom surface portion of said hole.

7. The mask for vacuum deposition as claimed in claim 1, wherein said tension applying means includes a through hole formed at a side wall of said guide member, a screw which is passed through said through hole and whose tip portion is screwed into a threaded hole formed at a side surface of said mask frame, and a spring member provided between said mask frame and said guide member.

8. The mask for vacuum deposition as claimed in claim 7, wherein said spring member is a compression spring.

9. The mask for vacuum deposition as claimed in claim 7, wherein said spring member is a leaf spring.

10. The mask for vacuum deposition as claimed in claim 1, wherein said fixing means for fixing said guide member and said mask frame in the vertical direction to the mask surface is a clip member for clipping the mask frame and the guide member in the longitudinal direction of the guide member.

11. The mask for vacuum deposition as claimed in claim 1, wherein said fixing means for fixing said guide member and said mask frame in the vertical direction to the mask surface is a clip member for clipping the mask frame and the guide member at four corners of the mask body for vacuum deposition.

12. The mask for vacuum deposition as claimed in claim 1, wherein said fixing means for fixing said guide member and said mask frame in the vertical direction to the mask surface comprises a through hole formed at a wall surface of the guide member, a through hole formed at a side surface of the mask frame, and a pin to be inserted into the through hole of said guide member and the through hole of said mask frame.

13. An organic EL display panel manufactured by the use of a mask for vacuum deposition that is held by a mask frame and comprises:
a mask body for vacuum deposition;
a guide member fixed to at least one side of said mask body for vacuum deposition;
a tension applying means for applying predetermined tension to said mask body for vacuum deposition via said guide member when said guide member is held by said mask frame; and
a fixing means for fixing said guide member and said mask frame in a vertical direction to a mask surface.

14. The organic EL display panel as claimed in claim 13, wherein said mask body for vacuum deposition has a mask pattern in which apertures are arranged in a predetermined pattern and has said guide member fixed to at least one side in the direction perpendicular to the longitudinal direction of said aperture.

15. The organic EL display panel as claimed in claim 13, wherein said tension applying means includes a threaded hole formed at a side wall of said guide member and a screw which is screwed into said threaded hole and whose tip portion is abutted against a side wall of said mask frame.

16. The organic EL display panel as claimed in claim 13, wherein said tension applying means includes a through hole formed at a side wall of said guide member, a screw which is passed through said through hole and whose tip portion is screwed into a threaded hole formed at a side wall of said mask frame, and a spring member provided between said mask frame and said guide member.

17. The organic EL display panel as claimed in claim 13, wherein said fixing means for fixing said guide member and said mask frame in the vertical direction to the mask surface is a clip member for clipping the mask frame and the guide member in the longitudinal direction of the guide member.

18. The organic EL display panel as claimed in claim 13, wherein said fixing means for fixing said guide member and said mask frame in the vertical direction to the mask surface is a clip member for clipping the mask frame and the guide member at four corners of the mask body for vacuum deposition.

19. The organic EL display panel as claimed in claim 13, wherein said fixing means for fixing said guide member and said mask frame in the vertical direction to the mask surface comprises a through hole formed at a wall surface of the guide member, a through hole formed at a side surface of the mask frame, and a pin passed through the through hole of said guide member and the through hole of said mask frame.
